(19) United States
(12) Patent Application Publication
(10) Pub. No.: US 2024/0324203 A1
(43) Pub. Date: Sep. 26, 2024

(54) MEMORY DEVICE AND MANUFACTURING METHOD THEREOF

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Jung Shik JANG, Icheon-si Gyeonggi-do (KR); Seok Min CHOI, Icheon-si Gyeonggi-do (KR); In Su PARK, Icheon-si Gyeonggi-do (KR)

(73) Assignee: SK hynix Inc., Icheon-si Gyeonggi-do (KR)

(21) Appl. No.: 18/459,216

(22) Filed: Aug. 31, 2023

(30) Foreign Application Priority Data
Mar. 20, 2023 (KR) 10-2023-0035768

(51) Int. Cl. H10B 43/27; H10B 41/27

(52) U.S. Cl. CPC H10B 43/27; H10B 41/27

(57) ABSTRACT

There are provided a memory device and a manufacturing method thereof. The memory device includes: a first stack structure including a plurality of first interlayer insulating layers and a plurality of conductive layers for first word lines, which are alternately stacked; and a second stack structure including a plurality of second interlayer insulating layers and a plurality of conductive layers for second word lines, which are alternately stacked; a first etch stop layer disposed between the first stack structure and the second stack structure; and a plurality of first word line contacts extending to the inside of the first stack structure through the second stack structure and the first etch stop layer.

### CROSS-REFERENCE TO RELATED APPLICATION

The present application claims priority under 35 U.S.C. § 119(a) to Korean patent application number 10-2023-0035768 filed on Mar. 20, 2023, in the Korean Intellectual Property Office, the entire disclosure of which is incorporated by reference herein.

### BACKGROUND

### 1. Technical Field

The present disclosure generally relates to a memory device and a manufacturing method thereof, and more particularly, a three-dimensional memory device and manufacturing method thereof.

### 2. Related Art

A memory device includes a memory cell array and a peripheral circuit connected to the memory cell array. The memory cell array may include a plurality memory cells capable of storing data, and the peripheral circuit may be configured to perform a general operation including a program operation, a read operation, an erase operation, and the like.

In order to improve integration of the memory device, the memory cell array may include three-dimensionally arranged memory cells on the peripheral circuit.

### SUMMARY

In accordance with an aspect of the present disclosure, there is provided a memory device including: a first stack structure including a plurality of first interlayer insulating layers and a plurality of conductive layers for first word lines, which are alternately stacked; and a second stack structure including a plurality of second interlayer insulating layers and a plurality of conductive layers for second word lines, which are alternately stacked; a first etch stop layer disposed between the first stack structure and the second stack structure; and a plurality of first word line contacts extending to the inside of the first stack structure through the second stack structure and the first etch stop layer.

In accordance with another aspect of the present disclosure, there is provided a memory device including: a first stack structure including a plurality of first interlayer insulating layers and a plurality of conductive layers for first word lines, which are alternately stacked; a first etch stop layer formed on the first stack structure; a second stack structure formed on the first etch stop layer, the second stack structure including a plurality of second interlayer insulating layers and a plurality of conductive layers for second word lines, which are alternately stacked; a second etch stop layer formed on the second stack structure; a third stack structure formed on the second etch stop layer, the third stack structure including a plurality of third interlayer insulating layers and a plurality of conductive layers for third word lines, which are alternately stacked; and a plurality of first word line contacts extending to the inside of the first stack structure through the third stack structure, the second etch stop layer, the second stack structure, and the first etch stop layer.

In accordance with still another aspect of the present disclosure, there is provided a method of manufacturing a memory device, the method including: forming a first stack structure in which first interlayer insulating layers and first sacrificial layers are alternately stacked; forming a first etch stop layer on the first stack structure; forming a second stack structure in which second interlayer insulating layers and second sacrificial layers are alternately stacked on the first etch stop layer; forming first holes through which the first stack structure is exposed via the second stack structure and the first etch stop layer; forming a second etch stop layer on the second stack structure; forming a third stack structure in which third interlayer insulating layers and third sacrificial layers are alternately stacked on the second etch stop layer; and forming second holes through which the second stack structure is exposed via the third stack structure and the second etch stop layer, and forming third holes connected to the first holes via the third stack structure and the second etch stop layer.

### BRIEF DESCRIPTION OF THE DRAWINGS

In the drawing figures, dimensions may be exaggerated for clarity of illustration. It will be understood that when an element is referred to as being “between” two elements, it is not necessarily the only element between the two elements; it may be the only element between two elements or it may be accompanied by one or more other elements. Like reference numerals refer to like elements throughout.

FIG. 1 is a block diagram illustrating a memory device in accordance with an embodiment of the present disclosure.

FIGS. 2A and 2B are perspective views illustrating overlapping structures of a peripheral circuit structure and a cell stack structure in accordance with embodiments of the present disclosure.

FIG. 3 is a circuit diagram illustrating a memory cell array and a row decoder in accordance with an embodiment of the present disclosure.

FIG. 4 is a sectional view illustrating a cell stack structure in accordance with an embodiment of the present disclosure.

FIGS. 5A to 5P are views illustrating a manufacturing method of the memory device in accordance with an embodiment of the present disclosure.

FIG. 6 is a sectional view illustrating a cell stack structure in accordance with another embodiment of the present disclosure.

FIG. 7 is a block diagram illustrating a configuration of a memory system in accordance with an embodiment of the present disclosure.

### DETAILED DESCRIPTION

The specific structural or functional description disclosed herein is merely illustrative for the purpose of describing embodiments of the claimed subject matter. The appurtenant claims should not be construed as being limited to the embodiments set forth herein.

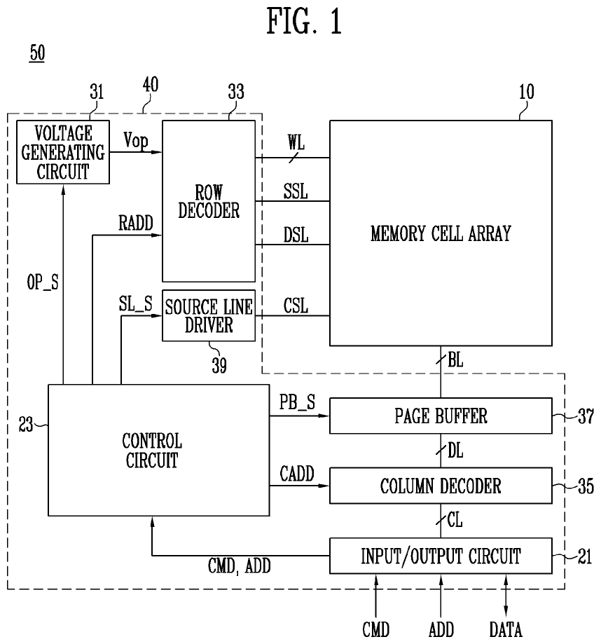

FIG. 1 is a block diagram illustrating a memory device 50 in accordance with an embodiment of the present disclosure. As used herein, the terms, peripheral and peripheral circuit refer to a device connected to or coupled (directly or indirectly) to a host and which is controlled by the host. A peripheral may feed data into the host but it may also receive data from the host.

Referring to FIG. 1, the semiconductor memory device 50 may include a peripheral circuit 40 and a memory cell array 10.

The peripheral circuit 40, which is coupled to the memory cell array 10, may be configured to perform a program operation to store data in the memory cell array 10, a read operation to retrieve or output data stored in the memory cell array 10, and an erase operation to delete or remove data stored in the memory cell array 10. In an embodiment and as shown in FIG. 1, the peripheral circuit 40 may include an input/output circuit 21, a control circuit 23, a voltage generating circuit 31, a row decoder 33, a column decoder 35, a page buffer 37, and a source line driver 39.

The memory cell array 10 may include a plurality of memory cells in which data is stored. The memory cells, which are not shown in FIG. 1, may be three-dimensional memory cells.

The memory cell array 10 may include one or more cell strings. Each cell string may include at least one drain select transistor, a plurality of memory cells, and at least one source select transistor, which are connected between any one of bit lines BL and a common source line CSL. The at least one drain select transistor may be connected to a drain select line DSL, the plurality of memory cells may be connected to a plurality of word lines, and the at least one source select transistor may be connected to a source select line.

The input/output circuit 21 may transfer, to the control circuit 23, a command CMD and an address ADD, which are received by the input/output circuit 23 from an external device, such as a memory controller for the memory device 50. The input/output circuit 21 may transmit data DATA it receives from the external device to the column decoder 35. The input/output circuit may also output to the external device, data DATA stored in the memory cell array, which the input/output circuit 21 receives from the column decoder 35.

The control circuit 23 may control the voltage generating circuit 31, the row decoder 32, the column decoder 35, the page buffer 37, and the source line driver 39 to perform a program operation, a read operation, or an erase operation, in response to a corresponding command CMD and an address ADD, which are received by the control circuit 23 from the input/output circuit 21. For example, the control circuit 23 may generate and output: an operation signal OP_S to the voltage generating circuit 31; a row address RADD to the row decoder 33; a source line control signal SL_S to the source line driver 39; a page buffer control signal PB_S to the page buffer 37; and a column address CADD to the column decoder, in response to a command CMD provided to the input/output circuit 21 by an external device not shown, and an address ADD that is also provided to the input/output circuit 21 by the external device.

The voltage generating circuit 31 may generate and output to the row decoder 33, various different operating voltages Vop, which are used for various different operations. Different operating voltages Vop are output to perform a program operation, a read operation, and an erase operation in response to the operation signal OP_S.

The row decoder 33 may selectively transfer the operating voltages Vop generated by the voltage generating circuit 31 to the drain select line DSL, the word lines WL, and the source select line SSL, in response to the row address RADD. The row decoder 33 may also selectively discharge voltages of the drain select line DSL, the word lines WL, and the source select line SSL.

The column decoder 35 may transmit data DATA received from the input/output circuit 21 to the page buffer 37 or transmit data DATA stored in the page buffer 37 to the input/output circuit 21 in response to the column address CADD. For example, in a program operation, the column decoder 35 may transmit data DATA received through column lines CL from the input/output circuit 21 to the page buffer 37 in response to the column address CADD. In a read operation, the column decoder 35 may receive data DATA stored in the page buffer 37 through data lines DL, and transmit the received data DATA to the input/output circuit 21.

In a program operation, wherein data is stored in the memory cell array 10, the page buffer 37 may temporarily store data DATA received from the column decoder 35, and control voltage of the bit lines BL, based on the temporarily stored data DATA. In a read operation, the page buffer 37 may sense data as a voltage on or a current through bit lines BL and latch sensed data DATA. The page buffer 37 may operate in response to the page buffer control signal PB_S.

The source line driver 39 may control a voltage applied to the common source line CSL in response to the source line control signal SL_S. For example, in an erase operation, the source line driver 39 may apply an erase voltage to the common source line CSL.

In order to increase integration density, i.e., store more data in a smaller volume, a memory cell stack structure of the memory cell array 10 may be formed such that the three-dimensional stack of memory cells is itself stacked above or below the peripheral circuit 40. For example, after a peripheral circuit structure is formed on a substrate, a memory cell stack structure, i.e., a three-dimensional stack of layers of memory cells, may be formed above or on top of the peripheral circuit structure.

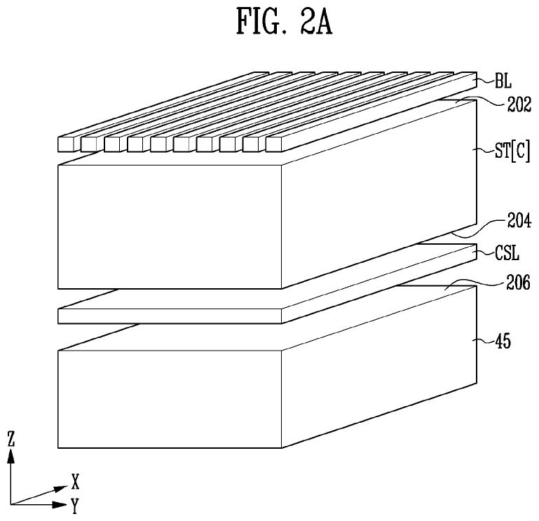

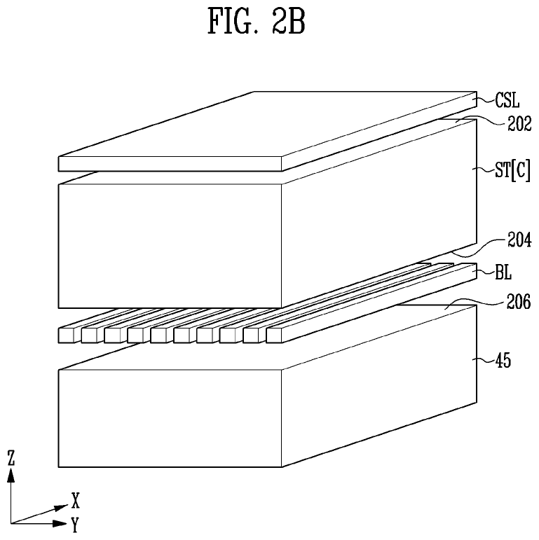

FIGS. 2A and 2B are perspective views illustrating a peripheral circuit structure and a memory cell stack structure in accordance with embodiments of the present disclosure.

In FIG. 2A a plurality of bit lines BL are overlaid a top surface 202 of a cell stack structure ST[C]. A common source line CSL is formed between the bottom surface 204 of the cell stack structure ST[C] and the top surface 206 of a peripheral circuit structure 45. The bit lines BL and the common source line CSL are thus considered herein as overlapping each other in the X-Y plane, the cell stack structure ST[C] layer disposed between the common source line CSL layer and another layer comprising the plurality of bit lines BL.

In FIG. 2B, the bit lines BL which comprise a layer, may be disposed between the cell stack structure ST[C] and the peripheral circuit structure 45. The common source line CSL, which comprises a layer, is overlaid the top surface 202 of the cell stack structure ST[C]. The bit lines BL layer and the common source line CSL layer are thus considered herein as overlapping each other in the X-Y plane with the cell stack structure ST[C] interposed between them.

In FIG. 2A and FIG. 2B, the entire cell stack structure ST[C] is depicted overlaid or on top of the entire peripheral circuit structure 45. In an alternate embodiment, however, only a partial region or portion of the cell stack structure ST[C] may overlay the peripheral circuit structure 45 and vice versa. That is, a partial region of the cell stack structure ST[C] and a partial region of the peripheral circuit structure 45 may overlay each other.

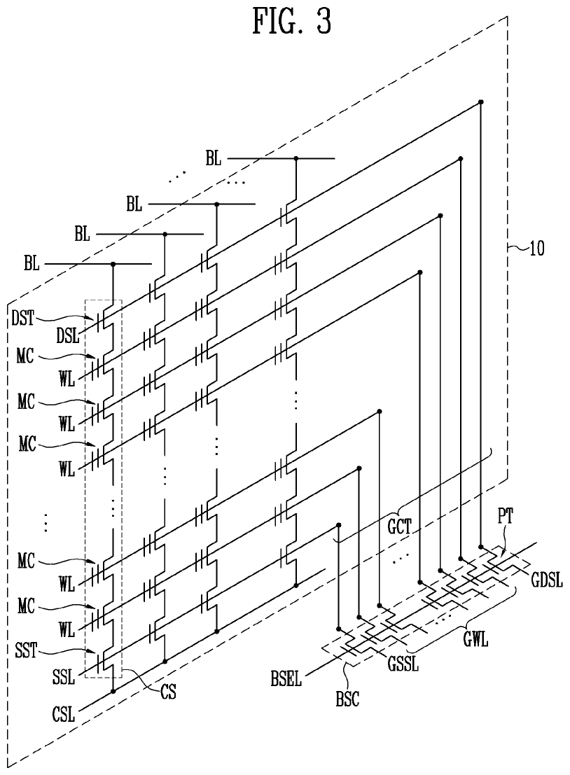

FIG. 3 is a circuit diagram illustrating a memory cell array and a row decoder in accordance with an embodiment of the present disclosure.

Referring to FIG. 3, the memory cell array 10 may include a plurality of cell strings CS, each cell string CS being connected to a corresponding bit line BL of the plurality of bit lines BL. The plurality of cell strings may be commonly connected to the common source line CSL.

Each cell string CS may include at least one source select transistor SST, a plurality of memory cells MC, and at least one drain select transistor DST, which are connected in series to each other and disposed between the common source line CSL and a bit line BL.

The source select transistor SST may control the connection of the cell string CS to the common source line CSL. The drain select transistor DST may control the connection of the cell string CS to the bit line BL.

One source select transistor SST may be disposed between the common source line CSL and the plurality of memory cells MC. In an alternate embodiment however, which is not shown in FIG. 3, two or more source select transistors, connected in series to each other, may be disposed between the common source line CSL and the plurality of memory cells MC. One drain select transistor DST may be disposed between the bit line BL and the plurality of memory cells MC. In an alternate embodiment however, which is not shown in FIG. 3, two or more drain select transistors connected in series to each other may be disposed between the bit line BL and the plurality of memory cells MC.

The plurality of memory cells MC may be respectively connected to word lines WL. Memory cell operation may thus be controlled by signals applied to the gates of the transistors that comprise each word line WL. The gates of the source select transistors SST may be connected to a source select line SSL. Source select transistor SST operation may thus be controlled by a signal applied to the gate to the source select line SSL. The gate of the drain select transistors DST may be connected to a drain select line DSL. Drain select transistor DST operation may thus be controlled by a signal applied to the drain select line DSL.

As shown in FIG. 3, the source select line SSL, the drain select line DSL, and the word lines WL may be connected to a block select circuit BSC, which may be included in the row decoder 33 described with reference to FIG. 1. In an embodiment, the block select circuit BSC may include pass transistors PT, one of which is respectively connected to the source select line SSL, the drain select line DSL, and each word line WL. Gates of the pass transistors PT may be connected to a block select line BSEL. The pass transistors PT of the block select circuit BSC, may thus, connect the source select line SSL of the memory cell array 10 to the global source select line GSSL connect the drain select line DSL of the memory cell array 10 to the global drain select line GDSL, and connect respective word lines WL of the memory cell array 10, to corresponding global word lines GWL, in response to the block select signal applied to the block select line BSEL.

The block select circuit BSC may be connected to the source select line SSL, the drain select line DSL, and the word lines WL via gate contact structures GCT, which are depicted in FIG. 3, as being within or part of the memory cell array 10.

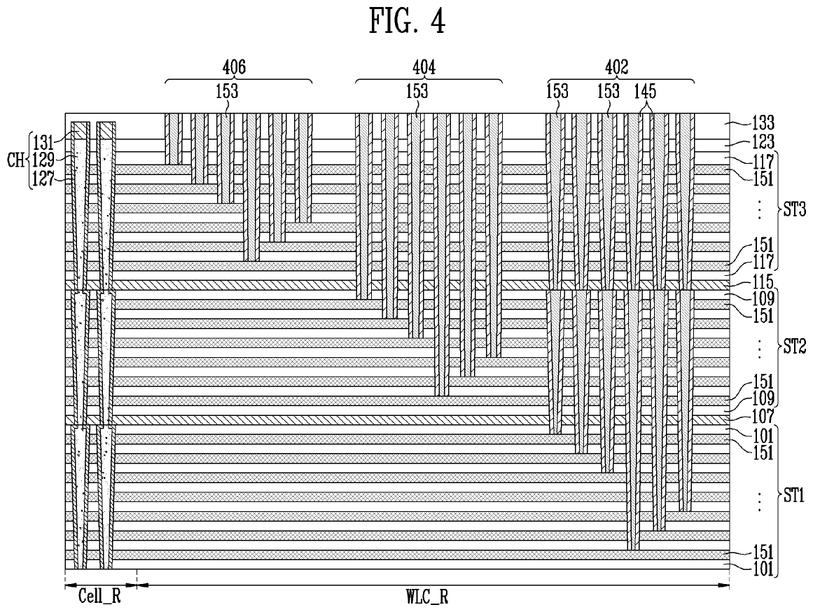

FIG. 4 is a vertical cross-sectional view illustrating a cell stack structure 400 for the memory device 50 depicted in FIG. 1, in accordance with an embodiment of the present disclosure.

Referring to FIG. 4, the cell stack structure 400 of the memory device 50 may include a plurality of stack structures designated ST1, ST2 and ST3. As shown in FIG. 4, the stack structures are stacked vertically. ST3 is above or “on top of” ST2; ST3 is above or “on top of ST1.

The first stack structure ST1 may include a plurality of interlayer insulating layers 101 and a plurality of conductive layers 151 for word lines. Insulting layers 101 and conductive layers 151 are alternately stacked on top of each other, by which is meant that insulating layers 101 and conductive layers 151 are interleaved, i.e., arranged in alternating layers. The plurality of first interlayer insulating layers 101 and the plurality of conductive layers 151 for word lines may be formed to be within and extend across both a cell region Cell_R and to extend across a word line contact region WLC_R.

For example, several first interlayer insulating layers 101 interleaved with several conductive layers 151 for word lines, may be formed to extend horizontally (as depicted in FIG. 4) between the cell region Cell_R to the word line contact region WLC_R.

A first etch stop layer 107, formed on top of a first interlayer insulating layer 101 may be disposed on and thus “define” or demarcate the first stack structure ST1. The first etch stop layer 107 is preferably a material having a high etch-selectivity relative to the etch selectivity of the material comprising the first interlayer insulating layers 101. For example, the first etch stop layer 107 may be formed of aluminum oxide (AIO), tungsten (W) or the like.

The second stack structure ST2 may be disposed on top of the first etch stop layer 107 and thus on top of the first stack structure ST1. The second stack structure ST2 may include a plurality of second interlayer insulating layers 109 and a plurality of conductive layers 151 for word lines, which are also alternately stacked, i.e., interleaved with each other. The plurality of second interlayer insulating layers 109 and the plurality of conductive layers 151 for word lines may be formed on both the cell region Cell_R and the word line contact region WLC_R. For example, the plurality of second interlayer insulating layers 109 and the plurality of conductive layers 151 for word lines may be formed to extend in the horizontal direction across the cell region Cell_R to, and across, the word line contact region WLC_R.

A second etch stop layer 115 may be disposed on a second interlayer insulating layer 109, which demarcates the second stack structure ST2. As with the first etch stop layer 107, the second etch stop layer 115 may be a material having a high etch selectivity relative to the etch selectivity of the material comprising the second interlayer insulating layers 109. For example, the second etch stop layer 115 may be formed of aluminum oxide (AIO), tungsten (W) or the like.

The third stack structure ST3 may be disposed on the second etch stop layer 115. The third stack structure ST3 may include a plurality of third interlayer insulating layers 117 and a plurality of conductive layers 151 for word lines, which are also alternately stacked. The plurality of third interlayer insulating layers 117 and the plurality of conductive layers 151 for word lines may be formed on the cell region Cell_R and the word line contact region WLC_R. For example, the plurality of third interlayer insulating layers 117 and the plurality of conductive layers 151 for word lines may be formed to extend in the horizontal direction from the cell region Cell_R to the word line contact region WLC_R.

The plurality of conductive layers 151 for word lines, which are included in each of the first stack structure ST1, the second stack structure ST2, and the third stack structure ST3 may extend in the horizontal direction to have the same length from the cell region Cell_R to the word line contact region WLC_R.

As described above and as shown in FIG. 4, the first etch stop layer 107 is disposed between the first stack structure ST1 and the second stack structure ST2, and the second etch stop layer 115 is disposed between the second stack structure ST2 and the third stack structure ST3. That is, the cell stack structure of the memory device comprises sequentially stacked, stack structures, with an etch stop layer disposed between stack structures that are vertically (as shown in FIG. 4) adjacent to each other.

Still referring to FIG. 4, at least one channel structure CH may be disposed within the cell region Cell_R and may extend vertically (as shown in FIG. 4). In the embodiment shown in FIG. 4, for example, the channel structure CH may extend vertically (as shown) through and thus penetrate, the first stack structure ST1, the first etch stop layer 107, the second stack structure ST2, the second etch stop layer 115, and the third stack structure ST3. The channel structure CH may include a substantially cone-shaped core insulating structure 129, which despite its substantially conical shape is referred to hereinafter as a core insulating layer 129. The core insulating layer 129 is substantially surrounded by a conically-shaped memory structure 127, which is referred to hereinafter as a memory layer 127. As shown in the figure, the core insulating layer 129 and the memory structure 127 have substantially equal vertical lengths and both extend vertically though the stack structures ST1, ST3 and ST3. A capping layer 131 in electrically contact with the memory layer 127 covers an upper surface of the core insulating layer 129. The memory layer 127 may include a channel layer surrounding the core insulating layer 129. Not shown in FIG. 4 is that a tunnel insulating layer may surround the channel layer, a data storage layer may surround the tunnel insulating layer, and a blocking insulating layer may surround the data storage layer. The data storage layer may be formed of a material layer capable of storing data changed using Fowler-Nordheim tunneling.

Still referring to FIG. 4, three separate groups 402, 404 and 406, of a plurality of word line contacts 153 respectively connected to the plurality of conductive layers 151 for word lines, may be disposed on the word line contact region WLC_R. The plurality of word line contacts 153 may be formed of a conductive material. Each of the plurality of word line contacts 153 may extend in the vertical direction to be connected directly to any one of a plurality of corresponding conductive layers 151 for word lines. Each of the plurality of word line contacts 153 may penetrate at least one conductive layer 151 for word lines, which is disposed above a corresponding conductive layer 151 for word lines in the vertical direction to be connected to the corresponding conductive layer 151 for word lines.

Among the plurality of word line contacts 153, a first group 402 of a plurality of word line contacts 153 extends to the inside of the first stack structure ST1 by extending through the third stack structure ST3, through the second etch stop layer 115, through the second stack structure ST2, and through the first etch stop layer 107, in order to be connected to the plurality of conductive layers 151 for word lines, WL, in the first stack structure ST1. The first group 402 of a plurality of word line contacts 153 may be defined as a plurality of first word line contacts. The plurality of first word line contacts may have different depths through the stacked stack structures, ST3, ST2 and ST1. A first word line contact at or near middle of the plurality of first word line contacts may have a deep depth through the stacked, stack structures whereas a first word line contact adjacent outer portions of the plurality of first word line contacts may have a relatively shallow depth.

Among the plurality of word line contacts 153, a second group 404 of a plurality of word line contacts 153 extending through the third stack structure ST3, through the second etch stop layer 115 to be connected to the plurality of conductive layers 151 for word lines WL in the second stack structure ST2, may be defined as a plurality of second word line contacts. The word lines of the plurality of second word line contacts may also have different depths depending on their separation distance from the center of the plurality of second word line contacts. For example, a second word line contact adjacent to the center of the plurality of second word line contacts may have a relatively deep depth, and a second word line contact adjacent to an outer portion of the plurality of second word line contacts may have a relatively shallow depth.

Among the plurality of word line contacts 153, a third group 406 of a plurality of word line contacts 153 extending to the third stack structure ST3, which are connected to the plurality of conductive layers 151 for word lines WL of the third stack structure ST3, may be defined as a plurality of third word line contacts. The plurality of third word line contacts may have different depths according to arrangement positions thereof. For example, a third word line contact adjacent to the center of the plurality of third word line contacts may have a relatively deep depth, and a third word line contact adjacent to an outer portion of the plurality of third word line contacts may have a relatively shallow depth.

A barrier layer 145 may be formed on the peripheral sidewalls of the plurality of word line contacts 153. The barrier layer 145 may extend vertically, surrounding the sidewalls of the plurality of word line contacts 153. The barrier layer 145 may allow word line contacts 153 and conductive layers 151 for word lines, which the plurality of word line contacts 153 penetrate, to be physically and electrically spaced apart from each other.

A first upper insulating layer 123 and a second upper insulating layer 133 may be formed on the top surface of the third stack structure ST3. The plurality of word line contacts 153 may thus penetrate the first upper insulating layer 123 and the second upper insulating layer 133.

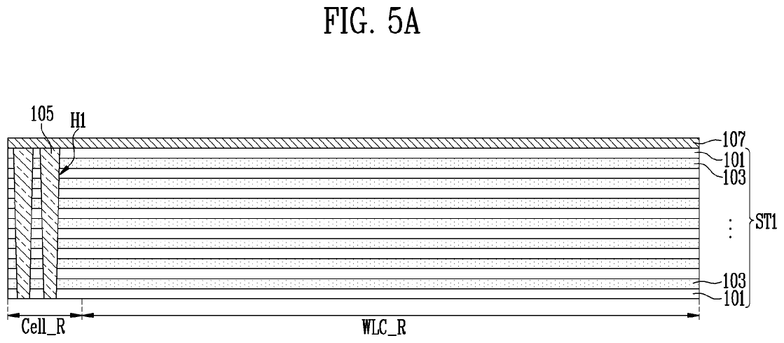

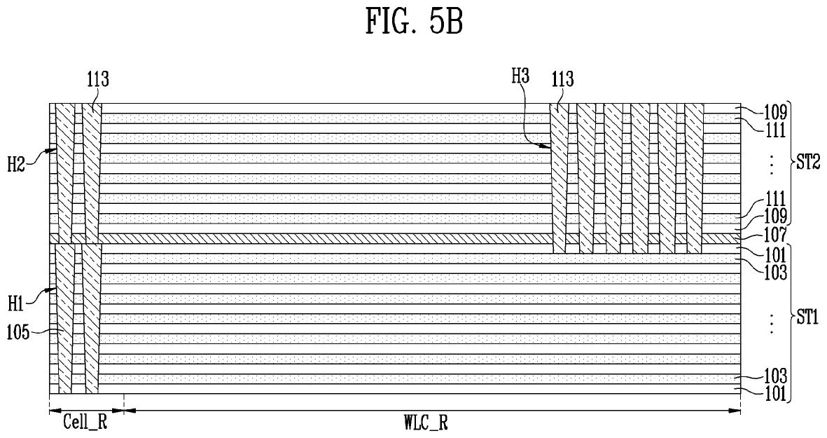

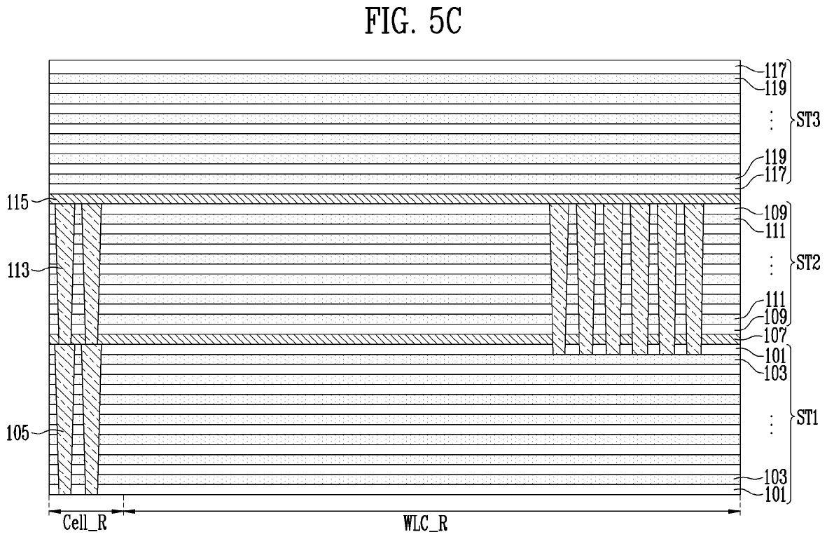

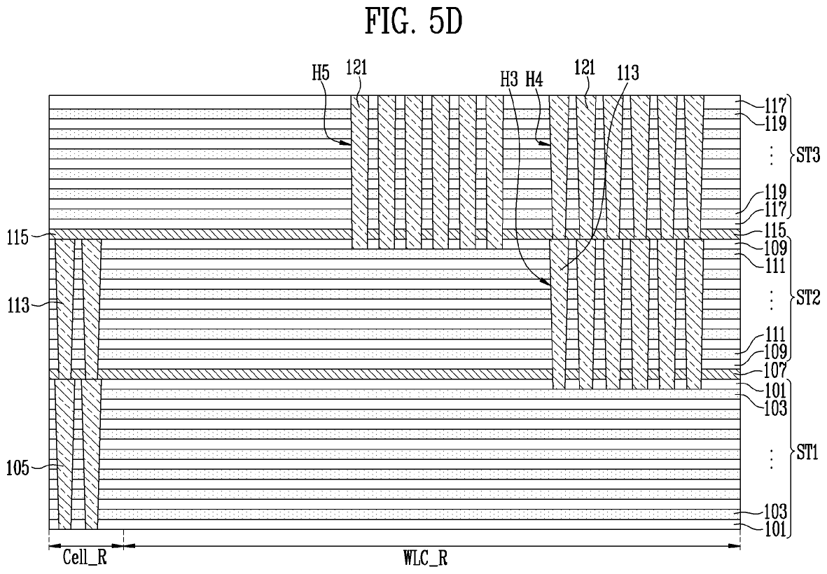

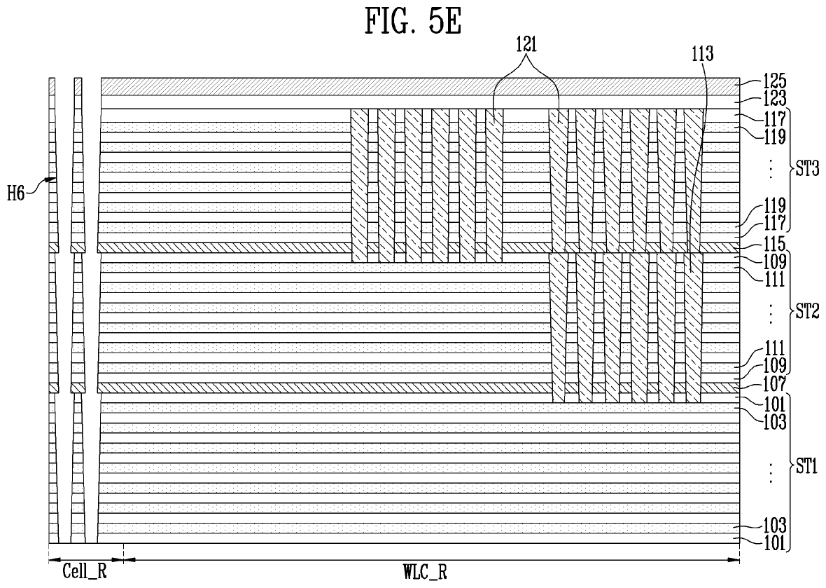

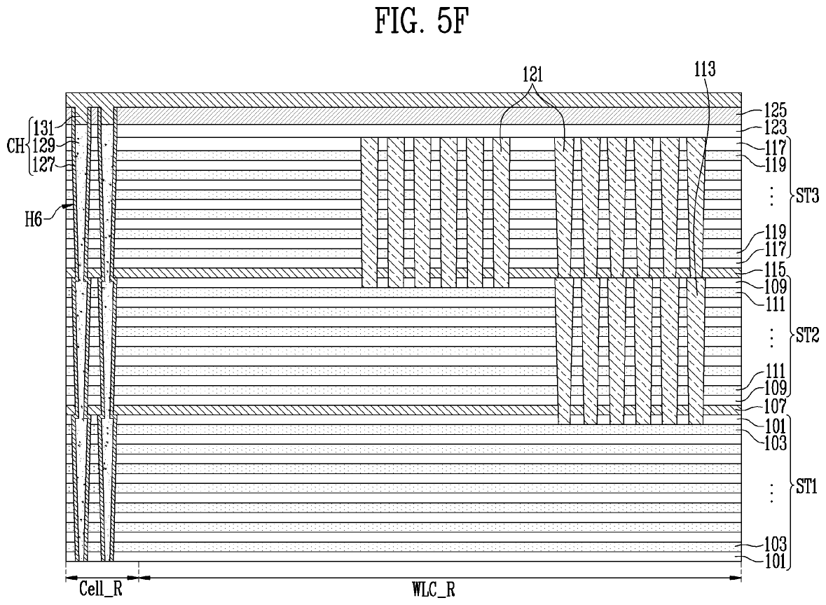

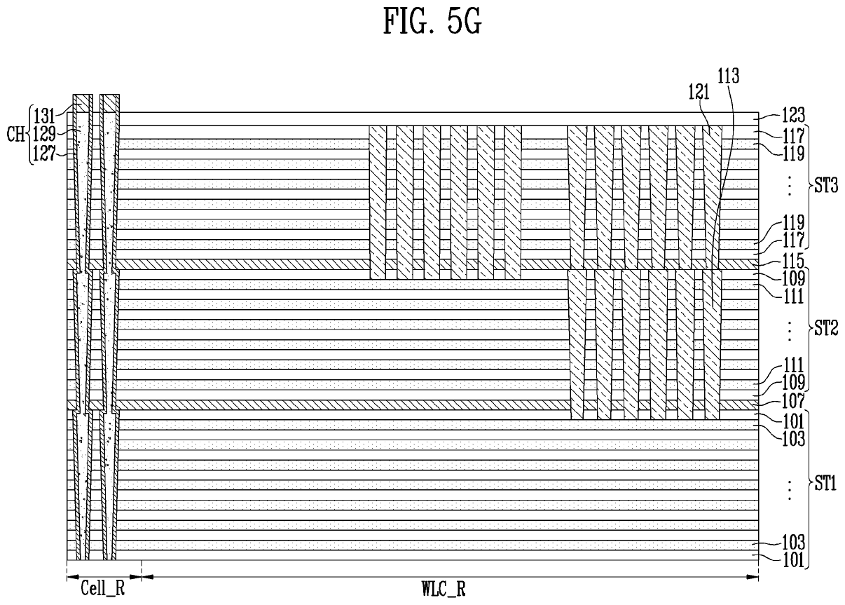

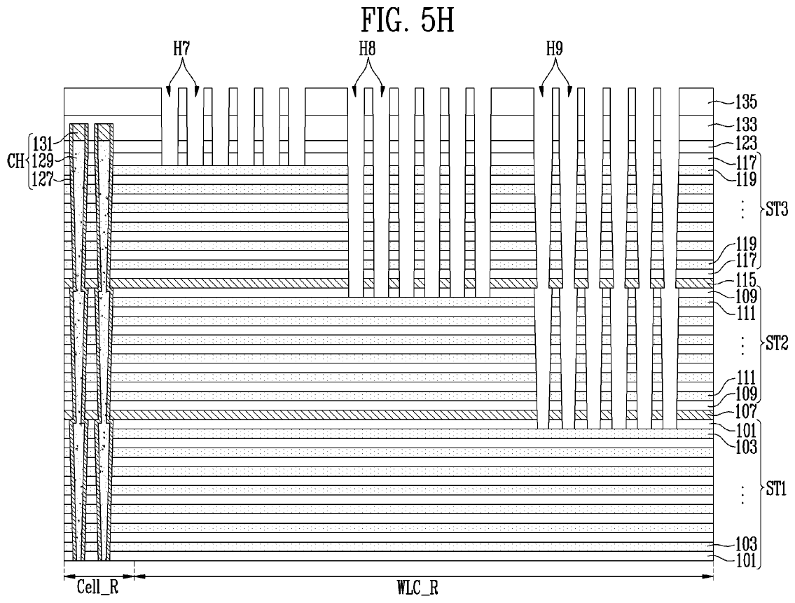

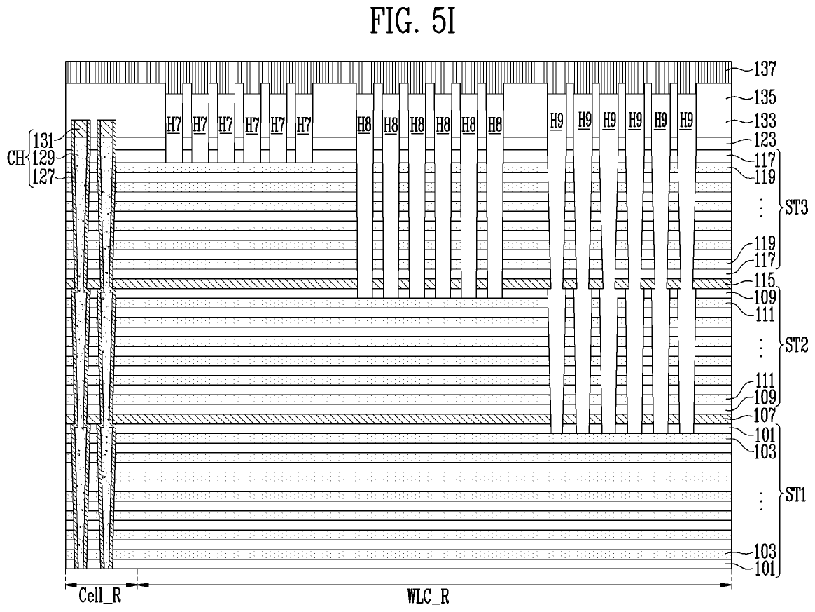

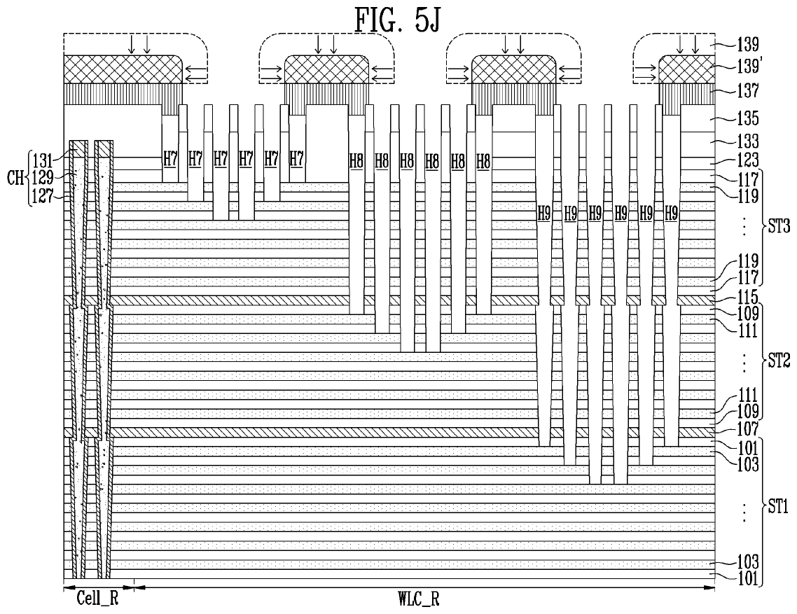

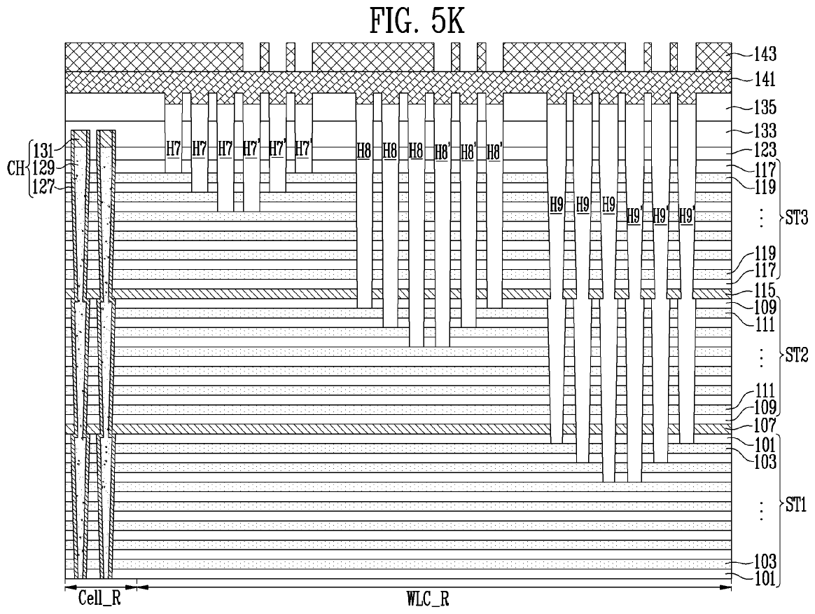

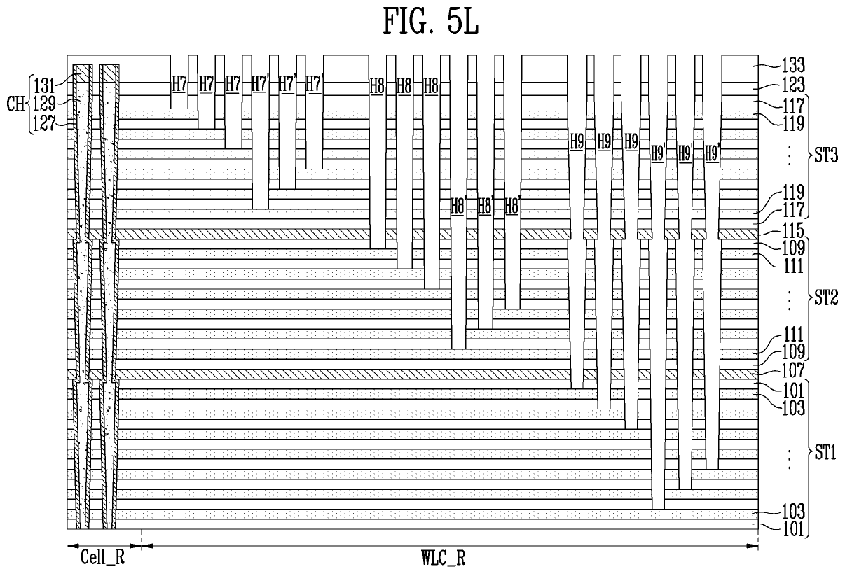

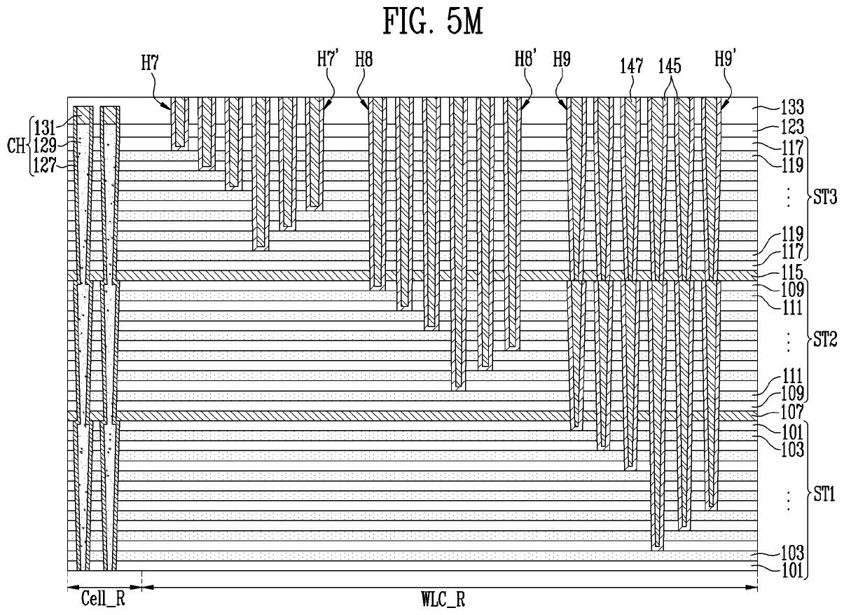

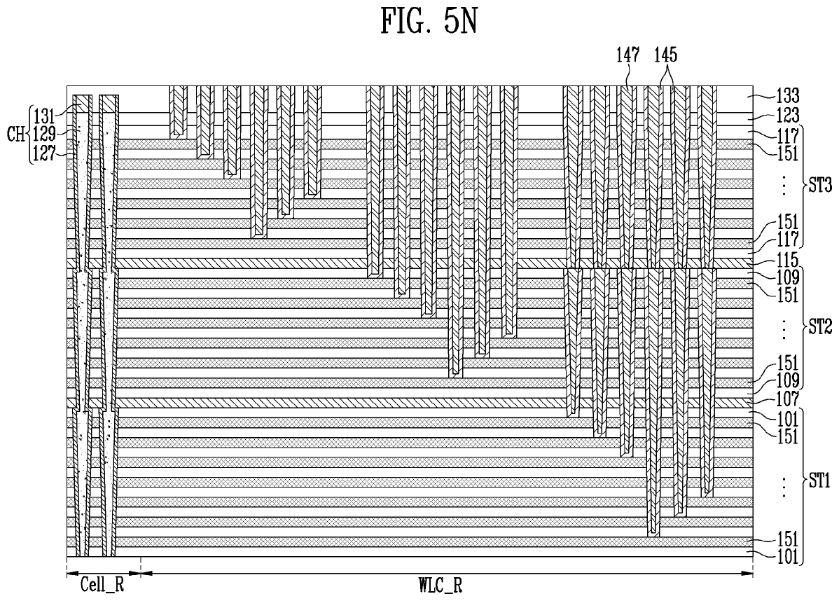

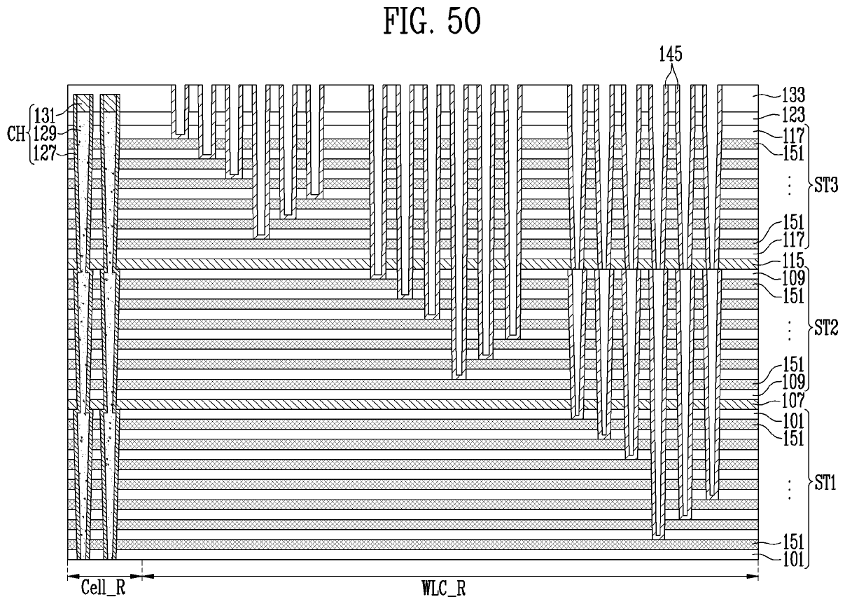

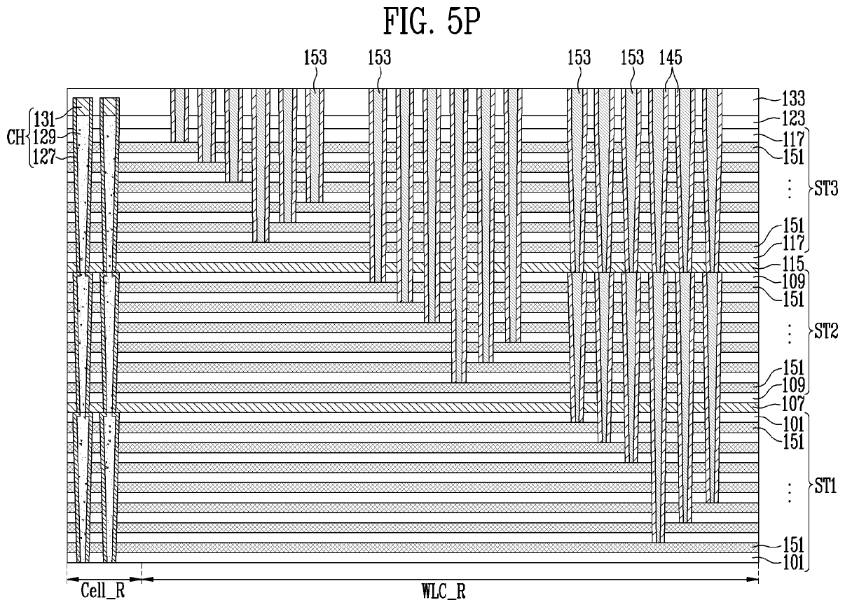

FIGS. 5A to 5P are views illustrating a method of making the memory device in accordance with an embodiment of the present disclosure.

Referring to FIG. 5A, a first stack structure ST1 may be formed by alternately stacking first interlayer insulating layers 101 and first sacrificial layers 103 on a semiconductor substrate (not shown). The first stack structure ST1 comprises cell region Cell_R and a word line contact region WLC_R. The first sacrificial layers 103 may include a material having an etch selectivity with respect to the first interlayer insulating layers 101. The first interlayer insulating layers 101 may be formed of an insulating material capable of insulating between conductive layers for word lines. In an embodiment, the first interlayer insulating layers 101 may include an oxide layer such as silicon oxide, and the first sacrificial layers 103 may include a nitride layer such as silicon nitride.

After the interleave layers 101 and 103 are formed, first holes H1 may be formed through the layers 101 and 103 in the cell region Cell_R. The first holes H1 penetrate each layer of the plurality of first interlayer insulating layers 101 and the plurality of first sacrificial layers 103 in a vertical direction.

After the holes H1 are formed, a first buried layer 105 is formed, which fills the first holes H1, The holes are filled, a first etch stop layer 107 may be formed on the first stack structure ST1 covering the first buried layer 105. The first etch stop layer 107 may be formed of a material having a high etch selectivity relative to the etch selectivity of the material comprising the first interlayer insulating layers 101 and the plurality of first sacrificial layers 103. For example, the first etch stop layer 107 may be formed of aluminum oxide (AIO), tungsten (W) or the like.

Referring to FIG. 5B, a second stack structure ST2 may be formed over the first stack structure ST1 by alternately stacking second interlayer insulating layers 109 and second sacrificial layers 111 on top of the first etch stop layer 107. The second sacrificial layers 111 may include a material having an etch selectivity with respect to the second interlayer insulating layers 109. The second interlayer insulating layers 109 may be formed of an insulating material capable of insulating between conductive layers for word lines. In an embodiment, the second interlayer insulating layers 109 may include an oxide layer such as silicon oxide, and the second sacrificial layers 111 may include a nitride layer such as silicon nitride.

As with ST1, second holes H2 overlapping the first holes H1 and the first buried layer 105 may be formed by etching the second stack structure ST2 and the first etch stop layer 107. As shown in FIG. 4 and FIG. 5B, the second holes H2 are also formed in the cell region Cell_R. In addition, third holes H3 penetrating the second stack structure ST2 in the vertical direction may be formed by etching the second stack structure ST2 and the first etch stop layer 107, which are formed on the word line contact region WLC_R. The third holes H3 may extend to the inside of a first interlayer insulating layer 101 disposed at the top of the first stack structure ST1.

After that, a second buried layer 113 may be formed, which fills both the second holes H2 and the third holes H3.

Referring now to FIG. 5C, a second etch stop layer 115 may be formed on the top of the second stack structure ST2 and the second buried layer 113, which filled the second and third holes. The second etch stop layer 115 may be formed of a material having a high etch selectivity relative to the etch selectivity of the material comprising the plurality of second interlayer insulating layers 109 and the plurality of second sacrificial layers 111. For example, the second etch stop layer 115 may be formed of aluminum oxide (AIO), tungsten (W) or the like.

A third stack structure ST3 may be formed by alternately stacking third interlayer insulating layers 117 and third sacrificial layers 119 on the second etch stop layer 115. The third sacrificial layers 119 may include a material having an etch selectivity with respect to the third interlayer insulating layers 117. The third interlayer insulating layers 117 may be formed of an insulating material capable of insulating between conductive layers for word lines. In an embodiment, the third interlayer insulating layers 117 may include an oxide layer such as silicon oxide, and the third sacrificial layers 119 may include a nitride layer such as silicon nitride.

Referring to FIG. 5D, fourth holes H4 penetrating the third stack structure ST3 in the vertical direction may be formed by etching the third stack structure ST3 and the second etch stop layer 115, which are formed in the word line contact region WLC_R. The fourth holes H4 may overlap with the third holes H3. When the fourth holes H4 are formed, they may expose the top or upper surfaces of the second buried layer 113 formed in the third holes H3. In addition, fifth holes H5 may be formed by etching the third stack structure ST3 and the second etch stop layer 115, which are formed on the word line contact region WLC_R. The fifth holes H5 may extend to the inside of a second interlayer insulating layer 109 disposed at an uppermost portion of the second stack structure ST2. The fourth holes H4 and the fifth holes H5 may be formed simultaneously or sequentially.

After the fourth holes H4 and fifth holes H5 are formed, a third buried layer 121 may be formed, which fills the fourth holes H4 and the fifth holes H5.

Referring to FIG. 5E, a first upper insulating layer 123 and a buffer layer 125 may be sequentially formed on the third stack structure ST3 and the third buried layer 121. The first upper insulating layer 123 may be formed of an oxide layer, and the buffer layer 125 may be formed of a nitride layer.

After that, the second buried layer (113 shown in FIG. 5D) formed on the cell region Cell_R may be exposed by sequentially etching the buffer layer 125, the first upper insulating layer 123, the third stack structure ST3, and the second etch stop layer 115, which are formed on the cell region Cell_R, and sixth holes H6 may be formed by removing the exposed second buried layer 113 and the first buried layer (105 shown in FIG. 5D). For example, the sixth holes H6 may be formed while penetrating the buffer layer 125, the first upper insulating layer 123, the third stack structure ST3, the second etch stop layer, the second stack structure ST2, the first etch stop layer 107, and the first stack structure ST1 in the vertical direction.

Referring to FIG. 5F, a memory layer 127 may be formed on the interior walls of the sixth holes H6 formed in the cell region Cell_R. The memory layer 127 may include a blocking insulating layer on the sidewalls of the sixth holes H6, a data storage layer extending in the vertical direction along an inner wall of the blocking insulating layer, a tunnel insulating layer extending in the vertical direction along an inner wall of the data storage layer, and a channel layer extending in the vertical direction along an inner wall of the tunnel insulating layer, which are not shown in FIG. 5F. The data storage layer may be formed of a material layer capable of storing data changed using Fowler-Nordheim tunneling.

After that, a core insulating layer 129 may be formed to fill central regions of the sixth holes H6. The core insulating layer 129 may extend in the vertical direction along an inner wall of the channel layer, and be formed of an oxide layer.

After that, an etching region in which a portion of an inner wall of the memory layer is exposed may be formed by etching a portion of a top end portion of the core insulating layer 129, and a capping layer 131 may be formed such that the etching region is buried. The capping layer 131 may be formed of a conductive material. For example, the capping layer 131 may be formed of a poly-silicon layer doped with an impurity. A channel structure CH may be defined to include the memory layer 127, the core insulating layer 129, and the capping layer 131.

Referring to FIG. 5G, the buffer layer (125 shown in FIG. 5F) is exposed by etching the capping layer 131 such that the capping layer 131 remains in only the etching region. After that, the exposed buffer layer (125 shown in FIG. 5F) may be removed. Accordingly, the channel structure CH may be formed to further protrude than the first upper insulating layer 123.

Referring to FIG. 5H, a second upper insulating layer 133 and a first mask layer 135 may be formed on the first upper insulating layer 123. The second upper insulating layer 133 may be formed to cover the protruding channel structure CH. The second upper insulating layer 133 may be formed of an oxide layer. The first mask layer 135 may be formed of a poly-silicon layer.

After that, a plurality of seventh holes H7 through which a third sacrificial layer 119 disposed at an uppermost portion of the third stack structure ST3 is exposed, a plurality of eighth holes H8 through which a second sacrificial layer 111 disposed at an uppermost portion of the second stack structure ST2 is exposed, and a plurality of ninth holes H9 through which a first sacrificial layer 103 disposed at an uppermost portion of the first stack structure ST1 is exposed may be formed by patterning the first mask layer 135 and performing an etching process using the patterned first mask layer 135.

For example, the plurality of seventh holes H7, and the plurality of eighth holes H8 and the plurality of ninth holes H9, which expose the third buried layer (121 shown in FIG. 5G) may be formed by etching the second upper insulating layer 133, the first upper insulating layer 123, and a third insulating layer 117 disposed at an uppermost portion of the third stack structure ST3 through the etching process using the patterned first mask layer 135. After that, the third buried layer (121 shown in FIG. 5G) may be removed thereby extending lower portions of the eighth holes H8, and the third buried layer (121 shown in FIG. 5G) and the second buried layer (115 shown in FIG. 5G) may be sequentially removed, thereby extending lower portion of the ninth holes H9.

As described above, the first and second etch stop layers 107 and 115 are formed between the plurality of stack structures ST1, ST2, and ST3, so that a problem can be reduced, in that a lower stack structure (e.g., ST2 or ST1) is excessively etched in an etching process for forming holes penetrating an upper stack structure (e.g., ST3 or ST2).

Referring to FIG. 5I, a cover layer 137 may be formed on the top of the entire structure to cover openings of the plurality of seventh holes H7, the plurality of eighth holes H8, and the plurality of ninth holes H9. The cover layer 137 may be formed of a carbon layer.

Referring to FIG. 5J, a second mask pattern 139 may be formed on the cover layer 137. Openings of the second mask pattern 139 may overlap with some holes among the plurality of seventh holes H7, some holes among the plurality of eighth holes H8, and some holes among the plurality of ninth holes H9. The second mask pattern 139 may include a photoresist.

Subsequently, the cover layer 137 may be etched by performing an etching process using the second mask pattern 139. Accordingly, some of the holes of the plurality of seventh holes H7, some of the holes of the plurality of eighth holes H8, and some holes of the plurality of ninth holes H9 may be exposed.

Subsequently, a third sacrificial layer 119 and a third interlayer insulating layer 117 on the bottom of the exposed holes of the seventh holes H7 may be etched, thereby extending the exposed seventh holes to the third stack structure ST3. In addition, a second sacrificial layer 111 and a second interlayer insulating layer 109 on the bottom of the exposed eighth holes H8 may be etched, thereby extending exposed eighth holes to the second stack structure ST2. In addition, a first sacrificial layer 103 and a first interlayer insulating layer 101 on the bottom of the exposed ninth holes H9 may be etched, thereby extending of the ninth holes the first stack structure ST1.

After that, a second mask pattern 139′ may be formed by reducing the size of the second mask pattern 139 through an etching process. The second mask pattern 139′ may additionally expose some holes among the plurality of seventh holes H7, additionally expose some holes among the plurality of eighth holes H8, and additionally expose some holes among the plurality of ninth holes H9. That is, a number of holes exposed by the second mask pattern 139′ may be increased compared to the number of holes exposed by the second mask pattern 139.

Subsequently, a third sacrificial layer 119 and a third interlayer insulating layer 117 on the bottom of the some holes among the plurality of seventh holes H7, which are exposed through the second mask pattern 139′, may be etched, thereby extending the some holes among the plurality of seventh holes H7 to the inside of the third stack structure ST3. In addition, a second sacrificial layer 111 and a second interlayer insulating layer 109 on the bottom of the some holes among the plurality of eighth holes H8, which are exposed through the second mask pattern 139′, may be etched, thereby extending the some holes among the plurality of eighth holes H8 to the inside of the second stack structure ST2. In addition, a first sacrificial layer 103 and a first interlayer insulating layer 101 on the bottom of the some holes among the plurality of ninth holes H9, which are exposed through the second mask pattern 139′, may be etched, thereby extending the some holes among the plurality of ninth holes H9 to the inside of the first stack structure ST1. Among the plurality of seventh holes H7, hoes which are exposed early may have a depth deeper than a depth of holes which are exposed later. Among the plurality of eighth holes H8, hoes which are exposed early may have a depth deeper than a depth of holes which are exposed later. Among the plurality of ninth holes H9, hoes which are exposed early may have a depth deeper than a depth of holes which are exposed later.

Reducing the second mask pattern 139′ and etching the first to third stack structures ST1 to ST3 may be repeated. Accordingly, the seventh holes H7, the eighth holes H8, and the ninth holes H9 may extend with various depths. The third sacrificial layers 119 of the third stack structure ST3 may be exposed by the seventh holes H7, the second sacrificial layers 111 of the second stack structure ST2 may be exposed by the eighth holes H8, and the first sacrificial layers 101 of the first stack structure ST1 may be exposed by the ninth holes H9.

Processes to extend the depths of the seventh holes H7, the eighth holes H8, and the ninth holes H9, which are described above, may be performed simultaneously or sequentially.

Referring to FIG. 5K, after the second mask pattern (139′ shown in FIG. 5J) and the cover layer (137 shown in FIG. 5J) are removed, a cover layer 141 may be formed on the top of the entire structure to cover the openings of the plurality of seventh holes H7, the plurality of eighth holes H8, and the plurality of ninth holes H9. The cover layer 141 may be formed of a carbon layer.

After that, a third mask pattern 143 may be formed on the top of the cover layer 141. Openings of the third mask pattern 143 may overlap/overlay some holes H7′ among the plurality of seventh holes H7, some holes H8′ among the plurality of eighth holes H8, and some holes H9′ among the plurality of ninth holes H9. The third mask pattern 143 may include a photoresist. For example, the openings of the third mask pattern 143 may overlap with a plurality of holes H7′ disposed at one side among the plurality of seventh holes H7, a plurality of holes H8′ disposed at one side among the plurality of eighth holes H8, and a plurality of holes H9′ disposed at one side among the plurality of ninth holes H9.

Referring to FIG. 5L, the cover layer (141 shown in FIG. 5K) may be etched using the third mask pattern (143 shown in FIG. 5K). Accordingly, the plurality of holes H7′ disposed at the one side among the plurality of seventh holes H7, the plurality of holes H8′ disposed at the one side among the plurality of eighth holes H8, and the plurality of holes H9′ disposed at the one side among the plurality of ninth holes H9, may be exposed.

Subsequently, a third sacrificial layer 119 and a third interlayer insulating layer 117 on the bottom of the plurality of exposed seventh holes H7′ disposed at the one side may be etched, thereby extending the plurality of seventh holes H7′ to the inside of the third stack structure ST3. In addition, a second sacrificial layer 111 and a second interlayer insulating layer 109 on the bottom of the plurality of exposed eighth holes H8′ disposed at the one side may be etched, thereby extending the plurality of eighth holes H8′ to the inside of the second stack structure ST2. In addition, a first sacrificial layer 103 and a first interlayer insulating layer 101 on the bottom of the plurality of exposed ninth holes H9′ disposed at the one side may be etched, thereby extending the plurality of ninth holes H9′ to the inside of the first stack structure ST1.

In an embodiment, the plurality of seventh holes H7 and H7′ may have a deeper depth as being located closer to a central portion thereof, and have a shallower depth as being located closer to an outer portion thereof. In addition, the plurality of eighth holes H8 and H8′ may have a deeper depth as being located closer to a central portion thereof, and have a shallower depth as being located closer to an outer portion thereof. In addition, the plurality of ninth holes H9 and H9′ may have a deeper depth as being located closer to a central portion thereof, and have a shallower depth as being located closer to an outer portion thereof. Processes of additionally extend the depths of the plurality of seventh holes H7′, the plurality of eighth holes H8′, and the plurality of ninth holes H9′ may be simultaneously performed or be sequentially performed.

In another embodiment, the plurality of seventh holes H7 and H7′, the plurality of eighth holes H8 and H8′, and the plurality of ninth holes H9 and H9′ may have a deeper depth as being more adjacent in one direction, and have a shallower depth as being more distant in the opposite direction of the one direction.

After that, the third mask pattern and the cover layer may be removed.

In an etching process of extending the depths of the plurality of seventh holes H7 and H7′, the plurality of eighth holes H8 and H8′, and the plurality of ninth holes H9 and H9′, described above in FIGS. 5J and 5L, side walls of the plurality of seventh holes H7 and H7′, the plurality of eighth holes H8 and H8′, and the plurality of ninth holes H9 and H9′ may be etched together. Therefore, the slope of an inflection portion at which the sidewall slope of the ninth holes H9 and H9′ is changed at a boundary portion of the second stack structure ST2 and the second etch stop layer 115 may be gently formed, and the width of the ninth holes H9 and H9′ may be formed constant.

Referring to FIG. 5M, after the first mask layer (135 shown in FIG. 5L) is removed, a barrier layer 145 may be formed along inner walls of the plurality of seventh holes H7 and H7′, the plurality of eighth holes H8 and H8′, and the plurality of ninth holes H9 and H9′. The barrier layer 145 may be formed of an oxide layer.

Subsequently, after a fourth buried layer 147 is formed such that the plurality of seventh holes H7 and H7′, the plurality of eighth holes H8 and H8′, and the plurality of ninth holes H9 and H9′ are buried, a planarization process may be performed such that the second upper insulating layer 133 is exposed. The planarization process may be performed as a Chemical Mechanical Polishing (CMP) process.

Referring to FIG. 5N, the first sacrificial layer (103 shown in FIG. 5M), the second sacrificial layer (111 shown in FIG. 5M), and the third sacrificial layer (119 shown in FIG. 5M) may be replaced with a conductive layer 151 for word lines. In an embodiment, after a slit (not shown) is formed in the third stack structure ST3, the second stack structure ST2, and the first stack structure ST1, the first sacrificial layer (103 shown in FIG. 5M), the second sacrificial layer (111 shown in FIG. 5M), and the third sacrificial layer (119 shown in FIG. 5M), which are exposed through the slit, may be selectively removed. After that, a conductive material may be filled in spaces in which the first sacrificial layer (103 shown in FIG. 5M), the second sacrificial layer (111 shown in FIG. 5M), and the third sacrificial layer (119 shown in FIG. 5M) are removed, thereby forming a plurality of conductive layers 151 for word lines. The plurality of conductive layers 151 for word lines may include a metal such as tungsten (W) or molybdenum (Mo).

Referring to FIG. 5O, after the slit (not shown) is filled with an insulating material, the fourth buried layer (147 shown in FIG. 5M) may be removed.

Referring to FIG. 5P, the barrier layer 145 formed at lower end portions of the plurality of seventh holes H7 and H7′, the plurality of eighth holes H8 and H8′, and the plurality of ninth holes H9 and H9′ may be selectively etched. Therefore, the conductive layers 151 for word lines may be exposed through the plurality of seventh holes H7 and H7′, the plurality of eighth holes H8 and H8′, and the plurality of ninth holes H9 and H9′. Through an etching process, the barrier layer 145 may remain on only inner walls of the plurality of seventh holes H7 and H7′, the plurality of eighth holes H8 and H8′, and the plurality of ninth holes H9 and H9′.

After that, the plurality of seventh holes H7 and H7′, the plurality of eighth holes H8 and H8′, and the plurality of ninth holes H9 and H9′ may be filled with a conductive material, thereby forming word line contacts 153. Each of the word line contacts 153 may be electrically and physically connected to each of the plurality of conductive layers 151 for word lines.

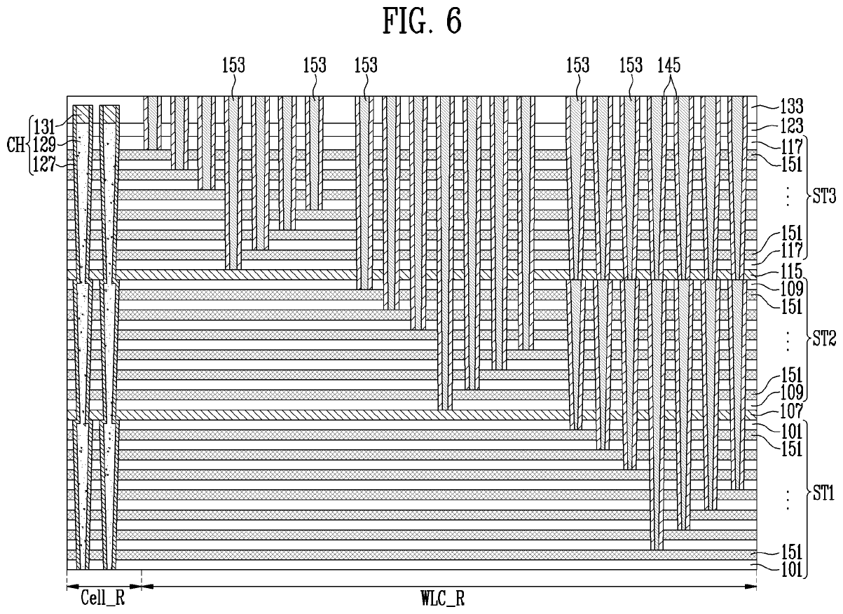

FIG. 6 is a vertical cross-sectional view illustrating a cell stack structure in accordance with another embodiment of the present disclosure.

Referring to FIG. 6, the cell stack structure of the memory device may include a plurality of stack structures. In such an embodiment, a structure in which a first stack structure ST1, a second stack structure ST2, and a third stack structure ST3 are sequentially stacked is hereinafter described as an exemplar.

The first stack structure ST may include a plurality of interlayer insulating layers 101 and a plurality of conductive layers 151 for word lines, which are alternately stacked. The plurality of first interlayer insulating layers 101 and the plurality of conductive layers 151 for word lines may be formed in both a cell region Cell_R and a word line contact region WLC_R. For example, the plurality of first interlayer insulating layers 101 and the plurality of conductive layers 151 for word lines may be formed to extend horizontally (as shown) from the cell region Cell_R to the word line contact region WLC_R.

A first etch stop layer 107 may be disposed on the first stack structure ST1. The first etch stop layer 107 may be formed of a material having a high etch selectivity relative to material that comprises the first interlayer insulating layers 101. For example, the first etch stop layer 107 may be formed of a conductive material such as tungsten (W). The first etch stop layer 107 may be used as a word line.

The second stack structure ST2 may be disposed on the first etch stop layer 107. The second stack structure ST2 may include a plurality of second interlayer insulating layers 109 and a plurality of conductive layers 151 for word lines, which are alternately stacked. The plurality of second interlayer insulating layers 109 and the plurality of conductive layers 151 for word lines may be formed on the cell region Cell_R and the word line contact region WLC_R. For example, the plurality of second interlayer insulating layers 109 and the plurality of conductive layers 151 for word lines may be formed to extend in the horizontal direction from the cell region Cell_R to the word line contact region WLC_R.

A second etch stop layer 115 may be disposed on the second stack structure ST2. The second etch stop layer 115 may be formed of a material having a high etch selectivity relative to the etch selectivity of the material comprising the second interlayer insulating layers 109. For example, the second etch stop layer 115 may be formed of a conductive material such as tungsten (W). The second etch stop layer 115 may be used as a word line.

The third stack structure ST3 may be disposed on the second etch stop layer 115. The third stack structure ST3 may include a plurality of third interlayer insulating layers 117 and a plurality of conductive layers 151 for word lines, which are alternately stacked. The plurality of third interlayer insulating layers 117 and the plurality of conductive layers 151 for word lines may be formed on the cell region Cell_R and the word line contact region WLC_R. For example, the plurality of third interlayer insulating layers 117 and the plurality of conductive layers 151 for word lines may be formed to extend in the horizontal direction from the cell region Cell_R to the word line contact region WLC_R.

As described above, the first etch stop layer 107 is disposed between the first stack structure ST1 and the second stack structure ST2, and the second etch stop layer 115 is disposed between the second stack structure ST2 and the third stack structure ST3. That is, the cell stack structure of the memory device includes a plurality of sequentially stacked stack structures, and an etch stop layer may be disposed between stack structures adjacent to each other. The etch stop layer may prevent the lower second stack structure ST2 from being excessively etched in a process of forming a hole penetrating the third stack structure ST3. The etch stop layer may be formed of a conductive material to be used as a word line.

At least one channel structure CH may be disposed on the cell region Cell_R. The channel structure CH may be disposed to extend in a vertical direction. For example, the channel structure CH may be disposed while penetrating the first stack structure ST1, the first etch stop layer 107, the second stack structure ST2, the second etch stop layer 115, and the third stack structure ST3 in the vertical direction. The channel structure CH may include a core insulating layer 129 extending in the vertical direction, a memory layer 127 extending in the vertical direction while surrounding a sidewall of the core insulating layer 129, and a capping layer 131 in contact with the memory layer 127 while covering an upper surface of the core insulating layer 129. The memory layer 127 may include a channel layer surrounding the core insulating layer 129, a tunnel insulating layer surrounding the channel layer, a data storage layer surrounding the tunnel insulating layer, and a blocking insulating layer surrounding the data storage layer. The data storage layer may be formed of a material layer capable of storing data changed using Fowler-Nordheim tunneling.

A plurality of word line contacts 153 respectively connected to the plurality of conductive layers 151 for word lines and the first and second etch stop layers 107 and 115 may be disposed on the word line contact region WLC_R. Also, the plurality of word line contacts 153 may be formed of a conductive material. Each of the plurality of word line contacts 153 may extend in the vertical direction to be directly connected to any one of a plurality of corresponding conductive layers 151 for word lines and the first and second etch stop layers 107 and 115. Each of the plurality of word line contacts 153 may penetrate at least one conductive layer 151 for word lines and the first and second etch stop layers 107 and 115, which are disposed on the top of a corresponding conductive layer 151 for word lines and the first and second etch stop layers 107 and 115, in the vertical direction for the purpose of connection of the corresponding conductive layer 151 for word lines and the first and second etch stop layers 107 and 115.

Among the plurality of word line contacts 153, a plurality of word line contacts 153 extending to the inside of the first stack structure ST1 through the third stack structure ST3, the second etch stop layer 115, the second stack structure ST2, and the first etch stop layer 107 to be connected to the plurality of conductive layers 151 for word lines in the first stack structure ST1 may be defined as a plurality of first word line contacts. The plurality of first word line contacts may have different depths according to arrangement positions thereof. A first word line contact adjacent to the center of the plurality of first word line contacts may have a relatively deep depth, and a first word line contact adjacent to an outer portion of the plurality of first word line contacts may have a relatively shallow depth.

Among the plurality of word line contacts 153, a plurality of word line contacts 153 extending to the inside of the third stack structure ST3 and the second etch stop layer 115 to be connected to the plurality of conductive layers 151 for word lines in the second stack structure ST2 may be defined as a plurality of second word line contacts. The plurality of second word line contacts may have different depths according to arrangement positions thereof. For example, a second word line contact adjacent to the center of the plurality of second word line contacts may have a relatively deep depth, and a second word line contact adjacent to an outer portion of the plurality of second word line contacts may have a relatively shallow depth.

Among the plurality of word line contacts 153, a plurality of word line contacts 153 extending to the inside of the third stack structure ST3 to be connected to the plurality of conductive layers 151 for word lines of the third stack structure ST3 may be defined as a plurality of word line contacts. The plurality of third word line contacts may have different depths according to arrangement positions thereof. For example, a third word line contact adjacent to the center of the plurality of third word line contacts may have a relatively deep depth, and a third word line contact adjacent to an outer portion of the plurality of third word line contacts may have a relatively shallow depth.

A barrier layer 154 may be formed on sidewalls of the plurality of word line contacts 153. The barrier layer 145 may extend in the vertical direction while surrounding the sidewalls of the plurality of word line contacts 153. The barrier layer 145 may allow a plurality of word line contacts 153, and at least one conductive layer 151 for word lines and the first and second etch stop layers 107 and 115, which the plurality of word line contacts 153 penetrate, to be physically and electrically spaced apart from each other.

A first upper insulating layer 123 and a second upper insulating layer 133 may be formed on the third stack structure ST3, and the plurality of word line contacts 153 may penetrate the first upper insulating layer 123 and the second upper insulating layer 133.

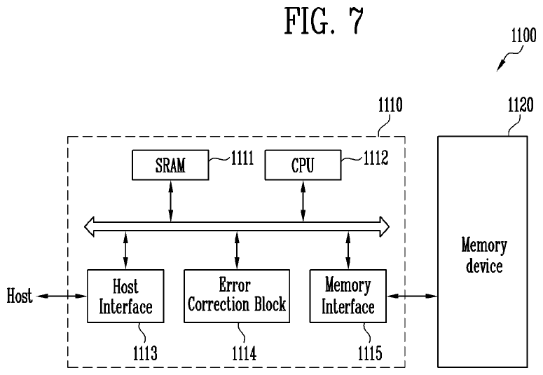

FIG. 7 is a block diagram illustrating a configuration of a memory system 1100 in accordance with an embodiment of the present disclosure.

Referring to FIG. 7, the memory system 1100 includes a memory device 1120 and a memory controller 1110.

The memory device 1120 may be a multi-chip package configured with a plurality of flash memory chips.

The memory device 1120 may include a peripheral circuit structure formed on a substrate as well as one or more stack structures formed on the peripheral circuit structure. The stack structure may include a cell stack structure described above. A gate contact structure connected to a gate conductive pattern of the cell stack structure may be connected to an interconnection structure included in the peripheral circuit structure while penetrating the cell stack structure.

The memory controller 1110 controls the memory device 1120, and may include a Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The error correction block 1114 detects an error included in a data read from the memory device 1120, and corrects the detected error. The memory interface 1115 interfaces with the memory device 1120. The memory controller 1110 may further include a Read Only Memory (ROM) for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

In accordance with the present disclosure, an etch stop layer is formed between a plurality of stack structures, so that a problem can be reduced, in that a lower stack structure is excessively etched in a process of forming a hole for forming a word line contact.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a first stack structure comprising a plurality of first interlayer insulating layers and a plurality of conductive layers for first word lines, which are alternately stacked; and
a second stack structure comprising a plurality of second interlayer insulating layers and a comprising a plurality of conductive layers for second word lines, which are alternately stacked;
a first etch stop layer disposed between the first stack structure and the second stack structure; and
a plurality of first word line contacts extending to the first stack structure by extending through the second stack structure and extending through the first etch stop layer.

2. The memory device of claim 1, wherein each word line of the plurality of first word line contacts, is connected to each conductive layer of the plurality of conductive layers.

3. The memory device of claim 1, further comprising:
a third stack structure comprising a plurality of third interlayer insulating layers and a plurality of conductive layers for third word lines, which are alternately stacked; and
a second etch stop layer disposed between the second stack structure and the third stack structure.

4. The memory device of claim 3, further comprising a plurality of second word line contacts extending to the inside of the second stack structure by extending through the third stack structure and extending through the second etch stop layer.

5. The memory device of claim 4, wherein each word line of the plurality of second word line contacts is connected to each conductive layer of the plurality of conductive layers for second word lines.

6. The memory device of claim 4, further comprising a plurality of third word line contacts extending to the third stack structure and which are connected to each of the plurality of conductive layers for third word lines.

7. The memory device of claim 6, wherein depths of the first word line contacts, the second word line contacts, and the third word line contacts are different.

8. The memory device of claim 7, wherein a depth of a first, first word line contact located proximate to the center of the plurality of first word line contacts, exceeds the depth of a second, first word line contact located away from the center of the plurality of first word line contacts, and
wherein depths of first word line contacts decrease as separation distances of the first word line contacts from the center of the plurality of first word line contacts increases.

9. The memory device of claim 4, wherein a depth of second word line contacts increases, as separation distances of second word line contacts from the center of the plurality of second word line contacts decreases, and
wherein depths of the second word line contacts decrease as separation distances of second word line contacts from the center of the plurality of second word line contacts increase.

10. The memory device of claim 6, wherein a depth of a third word line contact increases as a separation distance between the third word line contact and the center of the plurality of third word line contacts decreases.

11. The memory device of claim 1, wherein the first etch stop layer is a conductive layer for word lines.

12. The memory device of claim 6, further comprising a barrier layer extending in a vertical direction along a sidewall of each word line contact.

13. The memory device of claim 1, wherein the plurality of conductive layers for first word lines, the plurality of conductive layers for second word lines, and the plurality of conductive layers for third word lines are substantially horizontal and have substantially equal lengths.

14. A memory device comprising:
a first stack structure including a plurality of first interlayer insulating layers and a plurality of conductive layers for first word lines, which are alternately stacked;
a first etch stop layer formed on the first stack structure;
a second stack structure formed on the first etch stop layer, the second stack structure including a plurality of second interlayer insulating layers and a plurality of conductive layers for second word lines, which are alternately stacked;
a second etch stop layer formed on the second stack structure;
a third stack structure formed on the second etch stop layer, the third stack structure including a plurality of third interlayer insulating layers and a plurality of conductive layers for third word lines, which are alternately stacked; and
a plurality of first word line contacts extending to the first stack structure by extending through: the third stack structure; the second etch stop layer; the second stack structure; and the first etch stop layer.

15. The memory device of claim 14, further comprising a plurality of second word line contacts extending to the second stack structure by extending through the third stack structure and the second etch stop layer.

16. The memory device of claim 15, further comprising a plurality of third word line contacts extending to the third stack structure. third word lines.

17. The memory device of claim 14, wherein each of the first etch stop layer and the second etch stop layer is a conductive layer.

18. The memory device of claim 14, wherein the plurality of conductive layers for first word lines, the plurality of conductive layers for second word lines, and the plurality of conductive layers for third word lines are substantially horizontal and have substantially equal lengths.

19. The memory device of claim 14, wherein a depth of a first word line contact increases as a separation distance between the first word line contact and the center of the plurality of first word line contacts decreases.

20. The memory device of claim 15, wherein a depth of a second word line contact increases as a separation distance between the second word line contact and the center of the plurality of second word line contacts decreases.

21. The memory device of claim 16, wherein a depth of a third word line increases as a separation distance between the third word line contact and the center of the plurality of third word line contacts decreases.

22. A method of manufacturing a memory device, the method comprising:
forming a first stack structure comprising interleaved first interlayer insulating layers and first sacrificial layers;
forming a first etch stop layer on the first stack structure;
forming a second stack structure on the first etch stop layer, the second stack structure comprising interleaved second interlayer insulating layers and second sacrificial layers;
forming second holes in the second stack structure, which are configured to expose first holes formed in the first stack structure;
forming a second etch stop layer on the second stack structure;
forming a third stack structure in which third interlayer insulating layers and third sacrificial layers are alternately stacked on the second etch stop layer; and
forming third holes in the third stack structure, which are configured to expose the second holes formed in the second stack structure.

23. The method of claim 22, further comprising:
extending the second holes to the first stack structure such that a first sacrificial layer is exposed;
extending the third holes to the second stack structure such that a second sacrificial layer is exposed; and
forming fourth holes exposing each of the third sacrificial layers, the fourth holes extending to the inside of the third stack structure.

24. The method of claim 23, wherein the extending of the first holes to the inside of the first stack structure includes:
forming a mask pattern exposing at least one of the third holes;
etching the first stack structure by performing an etching process using the mask pattern;
increasing a number of the exposed third holes by reducing the mask pattern; and
etching the first stack structure by performing an additional etching process using the reduced mask pattern.

25. The method of claim 24, wherein, when the first holes extend to the inside of the first stack structure, the second holes extend to the inside of the second stack structure.

26. The method of claim 23, further comprising forming a plurality of word line contacts by filling the first to fourth holes with a conductive material.

27. The method of claim 26, further comprising forming a plurality of word lines connected to the plurality of word line contacts by replacing the first sacrificial layers, the second sacrificial layers, and the third sacrificial layers with conductive layers for word lines.

28. The method of claim 22, wherein each of the first etch stop layer and the second etch stop layer is a conductive layer for word lines.

29. A computer system comprising:
a processor;
a memory system, operatively coupled to the processor, the memory system storing program instructions for the processor, the memory system comprising:
a first stack structure comprising first interlayer insulating layers and conductive layers for first word lines, which are interleaved; and
a second stack structure comprising second interlayer insulating layers and conductive layers for second word lines, which are interleaved;
a first etch stop layer disposed between the first stack structure and the second stack structure; and
first word line contacts extending to the first stack structure by extending through the second stack structure and extending through the first etch stop layer.
